(19) United States
(12) Patent Application Publication
(10) Pub. No.: US 2026/0026243 A1
(43) Pub. Date: Jan. 22, 2026

(54) DISPLAY APPARATUS

(71) Applicant: Samsung Display Co., Ltd., Yongin-Si (KR)

(72) Inventors: Dogi Lim, Yongin-si (KR); Donguk Choi, Yongin-si (KR); Changjun Kim, Yongin-si (KR)

(21) Appl. No.: 19/170,353

(22) Filed: Apr. 4, 2025

(30) Foreign Application Priority Data
Jul. 16, 2024 (KR) 10-2024-0094003

(51) Int. Cl. H10K 59/80; H10K 59/131

(52) U.S. Cl. CPC H10K 59/873; H10K 59/131

(57) ABSTRACT

A display apparatus includes a substrate in a display area and a peripheral area outside the display area, a semiconductor layer disposed on the substrate in the display area, a gate layer disposed on the semiconductor layer, a conductive layer disposed on the gate layer, the conductive layer including a source electrode and a drain electrode electrically connected to the semiconductor layer and a common voltage line disposed in the display area and the peripheral area, at least one dam disposed on the conductive layer in the peripheral area, a support structure disposed outside of the at least one dam and overlapping an end of the common voltage line.

### CROSS-REFERENCE TO RELATED APPLICATION

This application is based on and claims priority, under 35 U.S.C. § 119, to Korean Patent Application No. 10-2024-0094003 filed on Jul. 16, 2024 in the Korean Intellectual Property Office, the disclosure of which is incorporated by reference herein in its entirety.

### BACKGROUND

### 1. Field

One or more embodiments relate to a display apparatus, and more particularly to a display apparatus with reduced occurrence of arc phenomenon.

### 2. Description of Related Art

Display apparatuses are configured to receive data about images and display the images using the data. Display apparatuses may be used as displays for small electronic devices such as mobile phones or large electronic devices such as televisions.

A display apparatus includes a plurality of pixels configured to receive electrical signals and emit light so as to externally display images. Each of the pixels includes a light-emitting element. For example, in the case of an organic light-emitting display apparatus, an organic light-emitting diode is included as the light-emitting element. In general, an organic light-emitting display apparatus includes a thin-film transistor and an organic light-emitting diode on a substrate. The organic light-emitting diode operates to emit light by itself.

### SUMMARY

One or more embodiments include a display apparatus in which an occurrence of an arc phenomenon is prevented or reduced. However, this is only an example and the scope of the disclosure is not limited thereby.

Additional aspects will be set forth in part in the description that follows and, in part, will be apparent from the description, or may be learned by practice of the presented embodiments of the disclosure.

According to one or more embodiments, a display apparatus having a display area and a peripheral area includes a substrate in the display area in which an image is displayed and the peripheral area outside the display area, a semiconductor layer disposed on the substrate in the display area, a gate layer disposed on the semiconductor layer, a conductive layer disposed on the gate layer, the conductive layer including a source electrode, a drain electrode, and a common voltage line, the source electrode and the drain electrode being electrically connected to the semiconductor layer in the display area and the common voltage line disposed in the display area and the peripheral area, at least one dam disposed on the conductive layer above the peripheral area, a support structure disposed outside of the at least one dam and overlapping an end of the common voltage line.

In an embodiment, the end of the common voltage line in the peripheral area may be closer to the display area than an outer edge of the support structure.

In an embodiment, the end of the common voltage line may be covered by the support structure in the peripheral area.

In an embodiment, the display apparatus may further include a mask support disposed on the support structure, and a mask disposed on the mask support.

In an embodiment, a distance between the end of the common voltage line and an edge of the mask may be less than a width of a base of the support structure.

In an embodiment, a width of the support structure may be greater than a width of the mask support.

In an embodiment, the support structure may include a first area that does not overlap the mask and a second area that overlaps the mask.

In an embodiment, a width of the second area may be greater than a width of the first area.

In an embodiment, a width of a base of the support structure may be about 500 micrometers to about 1,000 micrometers.

In an embodiment, the width of a base of the support structure may be about 650 micrometers.

In an embodiment, the common voltage line may be disposed on a same layer as the source electrode and the drain electrode.

In an embodiment, an area of the common voltage line that overlaps the support structure may be on a same layer as the source electrode and the drain electrode.

In an embodiment, the at least one dam may include a first dam disposed outside the display area and a second dam disposed at an outside of the first dam.

In an embodiment, the second dam may be between the first dam and the support structure.

In an embodiment, each of the support structure and the at least one dam may have a multilayer structure, and a lower layer of the support structure and a lower layer of the at least one dam may be formed on a same layer and may include a same material.

In an embodiment, an upper layer of the support structure and an upper layer of the at least one dam may be formed on a same layer and may include a same material.

In an embodiment, the upper layer of the support structure may be disposed on the lower layer of the support, and a lower surface of the upper layer of the support may be in direct contact with an upper surface of the lower layer of the support.

In an embodiment, the common voltage line may overlap the support structure and the at least one dam.

In an embodiment, the display apparatus may further include an inorganic insulating layer between the semiconductor layer and the gate layer, an organic insulating layer disposed on the conductive layer, a pixel electrode disposed on the organic insulating layer, an intermediate layer disposed on the pixel electrode, an opposite electrode disposed on the intermediate layer and electrically connected to the common voltage line in the peripheral area, and a thin-film encapsulation layer disposed on the opposite electrode.

In an embodiment, the thin-film encapsulation layer may include a first inorganic encapsulation layer disposed on the opposite electrode, an organic encapsulation layer disposed on the first inorganic encapsulation layer, and a second inorganic encapsulation layer disposed on the organic encapsulation layer, wherein the organic encapsulation layer may be in contact with an inner side surface of the at least one dam.

In another aspect, the disclosure pertains to an electronic device having a display area displaying images and a peripheral area outside of the display area, including: a substrate in the display area and the peripheral area, a thin-film transistor in the display area, the thin-film transistor including a semiconductor layer, a gate layer on the semiconductor layer, and a conductive layer disposed on the gate layer, wherein the conductive layer comprises a common voltage line that starts in the display area and has an end in the peripheral area, a dam disposed on the common volage line in the peripheral area; and a support structure disposed outside of the dam and overlapping the end of the common voltage line.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus according to an embodiment;

FIG. 2 is an equivalent circuit diagram schematically illustrating a pixel of the display apparatus of FIG. 1;

FIG. 3 is a cross-sectional view taken along line II-II′ of FIG. 1 and illustrating a portion of the display apparatus of FIG. 1;

FIG. 4 is a diagram for describing a support illustrated in FIG. 3;

FIG. 5 is a cross-sectional view schematically illustrating a portion of a peripheral area and a portion of a display area in a display apparatus according to a comparative example; and

FIG. 6 is a graph schematically showing a defect rate according to a width of a support of FIG. 3.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

It will be understood that, when a layer, film, region, or plate is referred to as being “on” another element, the layer, film, region, or plate may be “directly on” the other element, and intervening elements may be present therebetween. In addition, It will be understood that, when a layer, film, region, or plate is referred to as being “below” another element, the layer, film, region, or plate may be “directly below” the other element, and intervening elements may be present therebetween.

Also, sizes of elements in the drawings may be exaggerated or reduced for convenience of explanation. For example, because sizes and thicknesses of elements in the drawings are arbitrarily illustrated for convenience of explanation, the disclosure is not limited thereto. That is, for convenience of explanation, the size, thickness, and ratio of elements illustrated in the drawings may be exaggerated and/or simplified for clarity. Accordingly, spatially relative terms such as “below,” “under,” “lower,” “above,” “upper,” etc. are terms used herein to easily describe a relationship of one element or feature.

Terms used to describe space, direction, etc. in the present specification are terms for describing the space and direction illustrated in the drawings, but may be understood as terms for describing various other directions or various viewpoints. For example, when a device or element illustrated in the drawings is turned over, the device or element described as “below” may be interpreted in a different direction (e.g., rotated 90 degrees, an opposite direction, etc.). For example, when a device or element illustrated in the drawings is turned over, the device or element described as “on” may be interpreted as a different direction (e.g., rotated 90 degrees, an opposite direction, etc.). Accordingly, “below” and “on” may include both upward and downward directions. In addition, a device or element may be oriented differently from the drawings, and the description of space or direction described herein may be variously interpreted.

The order of processes or the order of methods understood in the description of processes, manufacturing methods, etc. in the present specification may be different from the stated order. For example, two consecutively described processes or methods may be performed simultaneously or substantially simultaneously or may be performed in the order opposite to the described order.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

It will be understood that the terms “first,” “second,” “third,” etc. may be used herein to describe specific elements, and the terms “first,” “second,” “third,” etc. may be only used to distinguish one element from another.

It will be understood that when an element is referred to as being “connected to” or “coupled to” another element, the element may be directly or indirectly connected to or combined with the other element.

Similarly, it will be understood that when an element is referred to as being “electrically connected to” another element, the element may be directly or indirectly electrically connected to the other element or may be directly or indirectly electrically connected to the other element through a conductive element.

In addition, it will be understood that when an element is referred to as being “between” two elements, the element may be understood as being the only element disposed between two elements, or elements other than the element may be disposed between the two elements.

The terms as used in the present specification are only used to describe specific embodiments and are not intended to limit the disclosure. The singular forms “a” and “an” as used herein are intended to include the plural forms as well unless the context clearly indicates otherwise.

For example, the expressions “mixing,” “mixture,” “mix,” “have,” etc. specify the presence of the stated features, integers, steps, operations, elements, and/or components, but do not exclude the presence or addition of one or more other features, integers, steps, operations, elements, components, and/or groups.

For example, the term “and/or” includes any and all combinations of one or more of the associated listed items. For example, the expression “A and/or B” indicates only A, only B, or both A and B. The expressions such as “at least one” may be used to indicate one or more elements among a plurality of elements. For example, the expressions “at least one of a, b, or c” and “at least one selected from a, b, and c” may indicate “only a,” “only b,” “only c,” “a and b,” “b and c,” “a and c,” or “all of a, b, and c.”

For example, “substantially,” “about,” and terms similar thereto are used as terms of approximation rather than terms of degree, and may be terms to describe inherent fluctuations in measured or calculated values that may be recognized by those of ordinary skill in the art. For example, terms such as “be able to,” “may,” etc. may be used to mean “one or more embodiments disclosed herein.”

For example, in the present specification, the expression “one layer has the same layer structure as another layer” may mean that a plurality of layers included in one layer may be included in the other layer in the same order. For example, a plurality of layers included in one layer and a plurality of layers included in another layer may each include the same material and may be formed in the same order.

Electronic or electrical devices and/or any other related devices or components (e.g., some of various modules) according to embodiments described herein may be implemented by using any suitable hardware, firmware (e.g., an application-specific integrated circuit), or a combination of software, firmware, and hardware. For example, the various components of these devices may be formed on one integrated circuit (IC) chip or on separate IC chips. Moreover, the various components of these devices may be formed on a flexible printed circuit film, a tape carrier package (TCP), a printed circuit board (PCB), or a single substrate. In addition, the various components of these devices may be processes or threads, may be executed on one or more processors, may execute computer program instructions on one or more computing devices, and may interact with other system components to perform various functions described herein.

The computer program instructions are stored in a memory that may be implemented in a computing device by using a standard memory device, such as random access memory (RAM). The computer program instructions may also be stored on, for example, other non-transitory computer-readable media, such as a compact disc read-only memory (CD-ROM) or flash drive. Furthermore, it will be understood by those of ordinary skill in the art that the functions of various computing devices may be combined or integrated into a single computing device, or the functions of particular computing devices may be distributed over one or more other computing devices without departing from the spirit and scope of the embodiments.

Hereinafter, a display apparatus according to an embodiment will be described in detail, based on the description provided below.

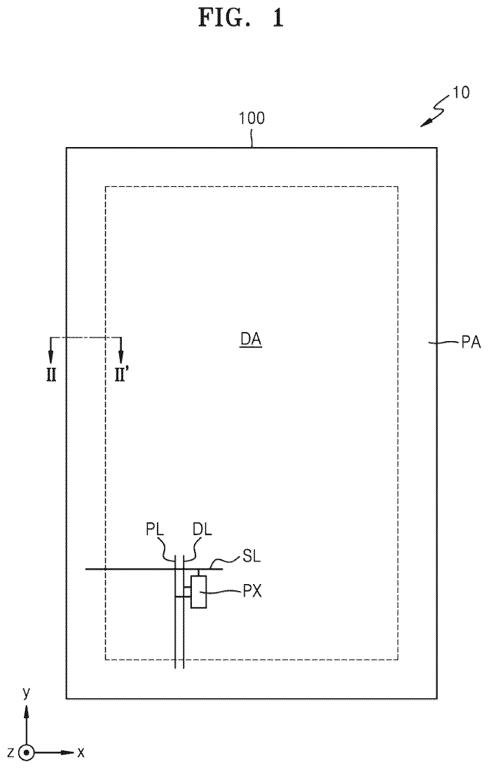

FIG. 1 is a plan view schematically illustrating a display apparatus according to an embodiment.

As illustrated in FIG. 1, the display apparatus according to an embodiment may include a display panel 10 configured to display an image. The display apparatus may be of any type as long as it includes the display panel 10. Examples of the display apparatus may include various devices, such as smartphones, tablets, laptops, televisions, or billboards. The display apparatus according to an embodiment may include thin-film transistors and capacitors. The thin-film transistors and the capacitors may be implemented by conductive layers and insulating layers.

The display panel 10 may include a display area DA and a peripheral area PA outside of the display area DA. Although FIG. 1 illustrates that the display area DA has a rectangular shape, the disclosure is not limited thereto. The display area DA may have other shapes, for example, a circular shape, an elliptical shape, a polygonal shape, or a specific figure shape.

The display area DA enables an image to be displayed, and a plurality of pixels PX may be disposed in the display area DA. Each of the pixels PX may include a display element, such as an organic light-emitting element. The pixels PX may be configured to externally emit, for example, red light, green light, or blue light. The pixel PX may be connected to a pixel circuit including a thin-film transistor, a storage capacitor, or the like. The pixel circuit may be connected to a scan line SL configured to transmit a scan signal, a data line DL crossing the scan line SL and configured to transmit a data signal, and a driving voltage line PL configured to supply a driving voltage. The data line DL and the driving voltage line PL may extend in a y-axis direction (or a first direction), and the scan line SL may extend in an x-axis direction (or a second direction).

The pixel PX may be configured to externally emit light having a luminance corresponding to an electrical signal output from the pixel circuit electrically connected thereto. The display area DA may enable a certain image to be displayed by light emitted from the pixel PX. The pixel PX as used herein may be defined as an emission area configured to emit one of red light, green light, and blue light.

The peripheral area PA may be an area in which pixels PX are not disposed, and thus, an image is not displayed in the peripheral area PA. Power supply lines for driving the pixels PX, common voltage lines to be described below, or the like may be disposed in the peripheral area PA. In addition, pads may be disposed in the peripheral area PA. The pads and integrated circuit (IC) devices, such as a printed circuit board or a driver IC including a driving circuit may be electrically connected to each other in the peripheral area PA.

The display panel 10 includes a substrate 100, and thus, it may be considered that the substrate 100 includes the display area DA and the peripheral area PA. Details of the substrate 100 are described below.

Also, a plurality of transistors may be disposed in the display area DA. A first terminal of the transistor may be a source electrode or a drain electrode and a second terminal of the transistor may be an electrode that is different from the first terminal, according to the type (N-type or P-type) of transistor and/or operating conditions. For example, when the first terminal is a source electrode, the second terminal may be a drain electrode.

For example, the transistors may include a driving transistor, a data write transistor, a compensation transistor, an initialization transistor, an emission control transistor, and the like. The driving transistor may be connected between the driving voltage line PL and an organic light-emitting element, and the data write transistor may be connected to the data line DL and the driving transistor and configured to perform a switching operation of transmitting a data signal transmitted to the data line DL.

The compensation transistor may be configured to be turned on in response to a scan signal received through the scan line SL and compensate for a threshold voltage of the driving transistor by connecting the driving transistor to the organic light-emitting element.

The initialization transistor may be configured to be turned on in response to the scan signal received through the scan line SL and initialize a gate electrode of the driving transistor by transmitting an initialization voltage to the gate electrode of the driving transistor. The scan line connected to the initialization transistor may be a separate scan line that is different from the scan line connected to the compensation transistor.

The emission control transistor may be configured to be turned on in response to an emission control signal received through an emission control line. As a result, a driving current may flow through the organic light-emitting element.

The organic light-emitting element may include a pixel electrode (an anode) and an opposite electrode (a cathode) and may be configured to receive a necessary voltage from the pixel electrode (the anode) and the opposite electrode (the cathode). The organic light-emitting element may be configured to display an image by emitting light according to the driving current received from the driving transistor.

Hereinafter, an organic light-emitting display will be described as an example of the display apparatus according to an embodiment, but the display apparatus according to the disclosure is not limited thereto. In another embodiment, examples of the display apparatus according to the disclosure may include an inorganic light-emitting display (or an inorganic electroluminescence (EL) display), a quantum dot light-emitting display, and the like. For example, an emission layer of a display element included in the display apparatus may include an organic material or an inorganic material. Also, the display apparatus may include an emission layer and quantum dots located on a path of light emitted from the emission layer.

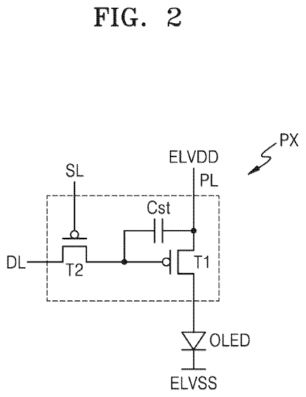

FIG. 2 is an equivalent circuit diagram schematically illustrating the pixel PX of the display apparatus of FIG. 1.

As illustrated in FIG. 2, the pixel PX may include a pixel circuit connected to a scan line SL and a data line DL, and an organic light-emitting element OLED connected to the pixel circuit.

For example, the pixel circuit may include a driving thin-film transistor T1, a switching thin-film transistor T2, and a storage capacitor Cst. The switching thin-film transistor T2 may be connected to the scan line SL and the data line DL and may be configured to transmit, to the driving thin-film transistor T1, a data signal input through the data line DL in response to a scan signal input through the scan line SL.

For example, the storage capacitor Cst may be connected to the switching thin-film transistor T2 and a driving voltage line PL and may be configured to store a voltage corresponding to a difference between a voltage received from the switching thin-film transistor T2 and a first power supply voltage (or a driving voltage) ELVDD supplied to the driving voltage line PL.

For example, the driving thin-film transistor T1 may be connected to the driving voltage line PL and the storage capacitor Cst and may be configured to control a driving current flowing from the driving voltage line PL to the organic light-emitting element OLED according to a voltage value stored in the storage capacitor Cst. The organic light-emitting element OLED may be configured to emit light having a certain luminance according to the driving current.

The organic light-emitting element OLED may be configured to receive a second power supply voltage (a common voltage) ELVSS. For example, the organic light-emitting element OLED may be configured to receive the second power supply voltage (the common voltage) ELVSS through an opposite electrode (a cathode), and the organic light-emitting element OLED may be configured to emit light having a certain luminance by the driving current according to the voltage difference between the first power supply voltage (the driving voltage) ELVDD and the second power supply voltage (the common voltage) ELVSS.

Although FIG. 2 illustrates that the pixel circuit includes two thin-film transistors and one storage capacitor, the disclosure is not limited thereto. For example, the pixel circuit may include two or more storage capacitors and may include three or more thin-film transistors.

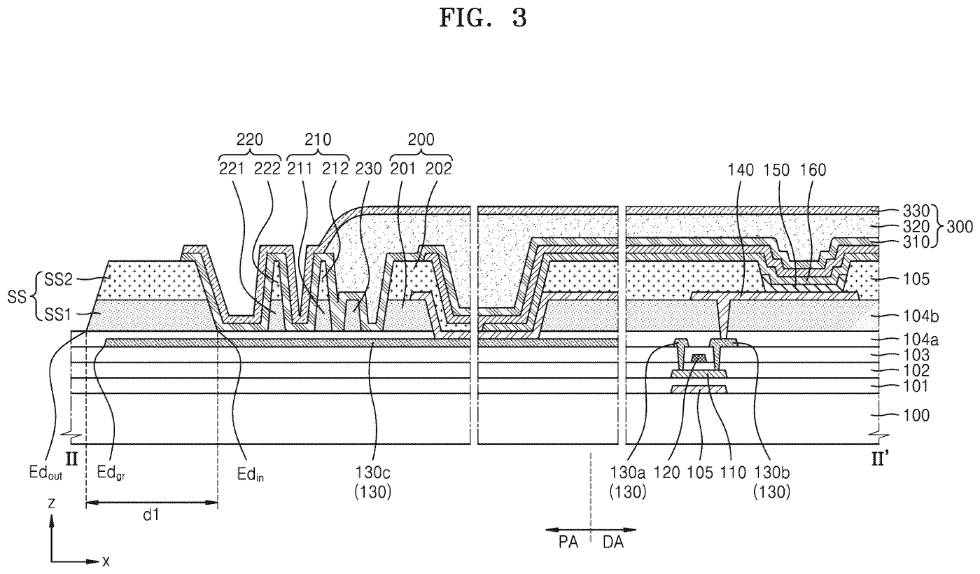

FIG. 3 is a cross-sectional view taken along line II-II′ of FIG. 1 and illustrating a portion of the display apparatus of FIG. 1.

As illustrated in FIG. 3, the display apparatus may include areas corresponding to a display area DA and a peripheral area PA outside of the display area DA. The substrate 100 is disposed in the display area DA and the peripheral area PA, and may include various flexible or bendable materials. For example, the substrate 100 may include glass, metal, or polymer resin. In addition, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. In some embodiments, other modifications are possible. For example, the substrate 100 may have a multilayer structure that includes two layers and a barrier layer therebetween, wherein the two layers may include polymer resin and the barrier layer may include an inorganic material (e.g., silicon oxide, silicon nitride, silicon oxynitride, etc.).

A buffer layer 101 may be disposed on the substrate 100. The buffer layer 101 may act as a barrier layer and/or a blocking layer that prevents impurity ions from diffusing, prevents infiltration of moisture or ambient air, and performs surface planarization. The buffer layer 101 may include silicon oxide, silicon nitride, or silicon oxynitride. Also, the buffer layer 101 may control the rate of heat supply during a crystallization process for forming a semiconductor layer 110 so that the semiconductor layer 110 is uniformly crystallized.

The semiconductor layer 110 may be disposed on the buffer layer 101. The semiconductor layer 110 may include polysilicon. The semiconductor layer 110 may include a channel region undoped with impurities, and a source region and a drain region formed by doping impurities into both sides of the channel region. The impurities may vary depending on the type of the thin-film transistor and may be an N-type impurity or a P-type impurity. Although not illustrated, the display apparatus according to the disclosure may further include another semiconductor layer disposed on another layer.

A gate insulating layer 102 may be disposed on the semiconductor layer 110. The gate insulating layer 102 may be configured to secure insulation between the semiconductor layer 110 and a gate layer 120. The gate insulating layer 102 may include an inorganic material, such as silicon oxide, silicon nitride, and/or silicon oxynitride, and may be between the semiconductor layer 110 and the gate layer 120. In addition, the gate insulating layer 102 may have a shape corresponding to the entire surface of the substrate 100 and may have a structure in which contact holes are formed in preset portions. The gate insulating layer 102 including the inorganic material may be formed by chemical vapor deposition (CVD) or atomic layer deposition (ALD). The same applies to embodiments and modifications to be described below.

The gate layer 120 may be disposed on the gate insulating layer 102. The gate layer 120 may be disposed at a position overlapping the semiconductor layer 110 and may include at least one metal selected from molybdenum (Mo), aluminum (AI), platinum (Pt), palladium (Pd), silver (Ag), magnesium (Mg), gold (Au), nickel (Ni), neodymium (Nd), iridium (Ir), chromium (Cr), nickel (Li), calcium (Ca), titanium (Ti), tungsten (W), and copper (Cu). Details of the gate layer 120 are described below. Although not illustrated, the display apparatus according to the disclosure may further include another gate layer disposed on another layer. As used herein, A and B “overlapping” means either A is on top of B or B is on top of A.

An interlayer insulating layer 103 may be disposed on the gate layer 120. The interlayer insulating layer 103 may cover the gate layer 120. The interlayer insulating layer 103 may include an inorganic material. For example, the interlayer insulating layer 103 may include metal oxide or metal nitride. Specifically, the interlayer insulating layer 103 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In some embodiments, the interlayer insulating layer 103 may have a dual structure of SiOₓ/SiN_{y} or SiNₓ/SiO_{y}.

A conductive layer 130 may be disposed on the interlayer insulating layer 103. The conductive layer 130 may act as an electrode connected to the source/drain region of the semiconductor layer through a through-hole included in the interlayer insulating layer 103.

The conductive layer 130 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer, and/or a Cu layer. For example, the conductive layer 130 may include a Ti/Al/Ti structure. For example, the conductive layer 130 may include a source electrode 130a electrically connected to the source region of the semiconductor layer 110 and a drain electrode 130b electrically connected to the drain region of the semiconductor layer 110.

Although not illustrated, the display apparatus according to the disclosure may further include another conductive layer disposed on another layer, and the other conductive layer may be, for example, a wiring layer that functions as a wiring. The other conductive layer may include the same material as that of the conductive layer 130 and may have the same layer structure as that of the conductive layer 130.

An inorganic protective layer (not shown) may cover the conductive layer 130 or the source electrode and the drain electrode of the conductive layer 130. The inorganic protective layer (not shown) may be a single layer or a multilayer including silicon nitride (SiNₓ) and silicon oxide (SiOₓ). The inorganic protective layer (not shown) may cover and protect some wirings disposed on the interlayer insulating layer 103.

For example, wirings (not shown) may be exposed in some areas of the substrate 100 (e.g., a portion of the peripheral area PA). The exposed portions of the wirings may be damaged by an etchant used to pattern the pixel electrode 140 to be described below. However, as in the present embodiment, because the inorganic protective layer (not shown) covers the data line DL and at least some wirings formed together with the data line DL, the wirings may be prevented from being damaged in the process of patterning the pixel electrode 140.

A first organic insulating layer 104a may be disposed on the conductive layer 130. The first organic insulating layer 104a may be an organic insulating layer acting as a planarization layer because the first organic insulating layer 104a covers the upper portion of the conductive layer 130 and has a substantially flat upper surface. The first organic insulating layer 104a may include, for example, an organic material, such as acrylic, benzocyclobutene (BCB), or hexamethyldisiloxane (HMDSO). The first organic insulating layer 104a may be variously modified. For example, the first organic insulating layer 104a may include a single layer or layers.

A second organic insulating layer 104b may be disposed on the first organic insulating layer 104a. The second organic insulating layer 104b may include, for example, an organic material, such as acrylic, BCB, or HMDSO. The second organic insulating layer 104b may be variously modified. For example, the second organic insulating layer 104b may include a single layer or layers.

Although not illustrated, the display apparatus according to the disclosure may further include another organic insulating layer disposed on another layer. The other organic insulating layer may be disposed on the other conductive layer described above and may act as a planarization layer by covering the upper portion of the other conductive layer. The other organic insulating layer may include the same material as that of the first and second organic insulating layers 104a and 104b and may have the same layer structure as that of the first and second organic insulating layers 104a and 104b.

A pixel electrode 140 may be disposed on the second organic insulating layer 104b. Alternatively, the pixel electrode 140 may be disposed on the other organic insulating layer described above. However, for convenience of explanation, it is assumed that the pixel electrode 140 is disposed on the second organic insulating layer 104b.

In the display area DA, the pixel electrode 140 may be connected to the conductive layer 130 through contact holes formed in the first organic insulating layer 104a and the second organic insulating layer 104b. In the display area DA, a display element may be disposed on the pixel electrode 140. An organic light-emitting element OLED may be used as the display element. That is, the organic light-emitting element OLED may be disposed on, for example, the pixel electrode 140. The pixel electrode 140 may include a transmissive conductive layer and/or a reflective layer. The transmissive conductive layer may include a transmissive conductive oxide, such as indium tin oxide (ITO), In₂O₃, or indium zinc oxide (IZO), and the reflective layer may include metal, such as Al or Ag. For example, the pixel electrode 140 may have a three-layer structure of ITO/Ag/ITO.

A pixel defining layer 105 may be disposed on the second organic insulating layer 104b and may be disposed to cover the edge of the pixel electrode 140. For example, the pixel defining layer 105 may cover the edge of the pixel electrode 140. The pixel defining layer 105 may have an opening corresponding to a pixel. The opening may be formed to expose at least the central portion of the pixel electrode 140. The opening may be defined by the pixel defining layer 105.

The pixel defining layer 105 may include, for example, an organic material, such as polyimide or HMDSO. In addition, a spacer (not shown) may be disposed on the pixel defining layer 105. The spacer (not shown) is illustrated as being disposed in the peripheral area PA, but may also be disposed in the display area DA. The spacer (not shown) may prevent the organic light-emitting element OLED from being damaged by sagging of a mask during a manufacturing process using a mask. The spacer (not shown) may include an organic insulating material and may include a single layer or layers.

An intermediate layer 150 and an opposite electrode 160 may be disposed on the opening described above. The intermediate layer 150 may include a low molecular weight material or a high molecular weight material. When the intermediate layer 150 includes a low molecular weight material, the intermediate layer 150 may include a hole injection layer, a hole transport layer, an emission layer, an electron transport layer, and/or an electron injection layer. When the intermediate layer 150 includes a high molecular weight material, the intermediate layer 150 may have a structure including a hole transport layer and an emission layer.

The structure of the intermediate layer 150 is not limited thereto and may have various structures. For example, at least one of layers constituting the intermediate layer 150 may be integrally formed as a single body like the opposite electrode 160. In another embodiment, the intermediate layer 150 may have a layer patterned to correspond to each of the pixel electrodes 140.

The opposite electrode 160 may include a transmissive conductive layer including a transmissive conductive oxide, such as ITO, In₂O₃, or IZO. The pixel electrode 140 may be used as an anode and the opposite electrode 160 may be used as a cathode. In some embodiments, the polarities of the pixel electrode 140 and the opposite electrode 160 may be reversed.

The opposite electrode 160 may be disposed above the display area DA, and the display area DA may be disposed on the front. That is, the opposite electrode 160 may be integrally formed as a single body to cover the pixels. The opposite electrode 160 may be in electrical contact with a common power supply (not shown) disposed in the peripheral area PA. For example, the opposite electrode 160 may extend to a partition wall 200 to be described below.

A thin-film encapsulation layer 300 may completely cover the display area DA and may extend toward the peripheral area PA to cover at least a portion of the peripheral area PA. The thin-film encapsulation layer 300 may extend to the outside of the partition wall 200.

The thin-film encapsulation layer 300 may include a first inorganic encapsulation layer 310, a second inorganic encapsulation layer 330, and an organic encapsulation layer 320 therebetween. The first inorganic encapsulation layer 310 and the second inorganic encapsulation layer 330 may each include at least one inorganic material selected from aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or layers including the inorganic material described above. The first inorganic encapsulation layer 310 and the second inorganic encapsulation layer 330 may include the same material as each other or may include different materials from each other.

The thickness of the first inorganic encapsulation layer 310 may be different from the thickness of the second inorganic encapsulation layer 330. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thickness of the first inorganic encapsulation layer 310 may be equal to the thickness of the second inorganic encapsulation layer 330.

The organic encapsulation layer 320 may include a monomer-based material or a polymer-based material. The polymer-based material may include acrylic-based resin, epoxy-based resin, polyimide, polyethylene, and the like. For example, the organic encapsulation layer 320 may include acrylate.

The partition wall 200 may be disposed on the peripheral area PA of the substrate 100. For example, the partition wall 200 may include a portion 221 of the second organic insulating layer 104b and a portion 212 of the pixel defining layer 105, but the disclosure is not necessarily limited thereto. For example, a lower layer of the partition wall 200 may be the portion 221 of the second organic insulating layer 104b, and an upper layer of the partition wall 200 may be the portion 212 of the pixel defining layer 105.

In some cases, the partition wall 200 may further include a portion (not shown) of the spacer (not shown). The portion (not shown) of the spacer (not shown) may be disposed on the portion 212 of the pixel defining layer 105, and the portion 212 of the pixel defining layer 105 may be disposed on the portion 221 of the second organic insulating layer 104b.

The partition wall 200 may surround the display area DA and may prevent the organic encapsulation layer 320 of the thin-film encapsulation layer 300 from overflowing to the outside of the substrate 100.

According to another embodiment, the thin-film encapsulation layer 300 may be replaced with a cover member that covers the entire display area DA. The cover member may be disposed to cover not only the display area DA but also at least a portion of the peripheral area PA. The cover member may include a rigid member (e.g., glass, etc.). When the thin-film encapsulation layer 300 is replaced with the cover member, the partition wall 200 may be omitted. In some cases, a transparent filler may be between the cover member and the opposite electrode 160.

At least one dam 210, 220, and 230 may be disposed in the peripheral area PA. FIG. 3 illustrates a structure in which two dams 210 and 220 of similar height are disposed next to a shorter dam 230. The at least one dam 210, 220, and 230 may block the organic material from flowing toward the edge of the substrate 100 when forming the organic encapsulation layer 320 of the thin-film encapsulation layer 300. Accordingly, the formation of an edge tail of the organic encapsulation layer 320 may be prevented.

The at least one dam 210, 220, and 230 may be disposed to surround at least a portion of the display area DA on the peripheral area PA. When a plurality of dams are provided, for example, when a first dam 210 and a second dam 220 are provided, the first dam 210 and the second dam 220 may be apart from each other and the first dam 210 may be surrounded by at least a portion of the second dam 220.

The at least one dam 210, 220, and 230 may further include an additional dam 230. The additional dam 230 may be disposed closer to the display area DA than the first dam 210. For example, the additional dam 230 may be farther from the outer edge of the display panel 10 than the first dam 210.

Although not illustrated, at least a portion of the at least one dam 210 and 220 may be disposed to overlap a driving circuit. For example, one of the first dam 210 and the second dam 220 may be disposed to overlap the driving circuit, or both the first dam 210 and the second dam 220 may be disposed to overlap the driving circuit.

The at least one dam 210, 220, and 230 may have various layer structures. For example, one of the first dam 210 and the second dam 220 may have a single-layer structure, and the other of the first dam 210 and the second dam 220 may have a multilayer structure. The additional dam 230 may have a single-layer structure or a multilayer structure.

FIG. 3 illustrates that each of the first dam 210 and the second dam 220 has a two-layer structure. Lower layers 211 and 221 of the first dam 210 and the second dam 220 and a lower layer 201 of the partition wall 200 may include the same material as, for example, the second organic insulating layer 104b and may be on the same layer as the second organic insulating layer 104b. For example, the lower layers 211 and 221 of the first dam 210 and the second dam 220 and the lower layer 201 of the partition wall 200 may include have the same layer structure as that of the second organic insulating layer 104b. For example, the lower layer 211 of the first dam 210, the lower layer 221 of the second dam 220, and the lower layer 201 of the partition wall 200 may be simultaneously formed in the same process as that of the second organic insulating layer 104b.

The upper layer 212 of the first dam 210, the upper layer 222 of the second dam 220, and an upper layer 202 of the partition wall 200 may include the same material as that of the pixel defining layer 105 and may be disposed on the same layer as the pixel defining layer 105. For example, the upper layer 212 of the first dam 210, the upper layer 222 of the second dam 220, and the upper layer 202 of the partition wall 200 may have the same layer structure as that of the pixel defining layer 105. For example, the upper layer 212 of the first dam 210, and the upper layer 222 of the second dam 220, the upper layer 202 of the partition wall 200 may be simultaneously formed in the same process as that of the pixel defining layer 105.

FIG. 3 illustrates that the additional dam 230 has a single-layer structure. For example, the additional dam 230 and the lower layer 201 of the partition wall 200 may include the same material as that of the second organic insulating layer 104b and may be disposed on the same layer as the second organic insulating layer 104b. For example, the additional dam 230 and the lower layer 201 of the partition wall 200 may include the same layer structure as that of the second organic insulating layer 104b. For example, the additional dam 230 and the lower layer 201 of the partition wall 200 may be simultaneously formed in the same process as that of the second organic insulating layer 104b.

The first inorganic encapsulation layer 310 of the thin-film encapsulation layer 300 may extend into the peripheral area PA while covering the display area DA, covering at least a portion of the at least one dam 210, 220, and 230.

For example, the organic encapsulation layer 320 may be in contact with the inner surface of the at least one dam 210, 220, and 230 facing the display area DA. The expression “the organic encapsulation layer 320 is in contact with the inner surface of the at least one dam 210, 220, and 230 may be understood as meaning that the first inorganic encapsulation layer 310 is between the organic encapsulation layer 320 and the at least one dam 210, 220, and 230 and the organic encapsulation layer 320 is in contact with the first inorganic encapsulation layer 310. The first inorganic encapsulation layer 310 and the second inorganic encapsulation layer 330 may be disposed on the at least one dam 210, 220, and 230 and may extend toward the edge of the substrate 100.

Accordingly, the organic encapsulation layer 320 may be in contact with the inner surface of the first dam 210 facing the display area DA. The first dam 210 may prevent the organic encapsulation layer 320 from flowing beyond the first dam 210.

For example, the organic encapsulation layer 320 of the thin-film encapsulation layer 300 may extend to the peripheral area PA while covering the display area DA, but the area may be limited by a dam (e.g., the first dam 210) before reaching the outermost dam (e.g., the second dam 220).

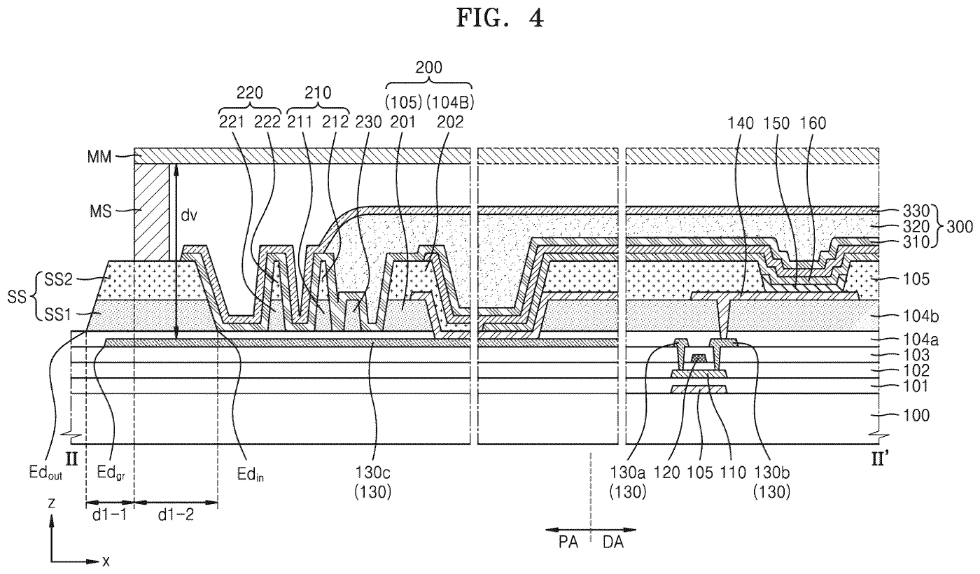

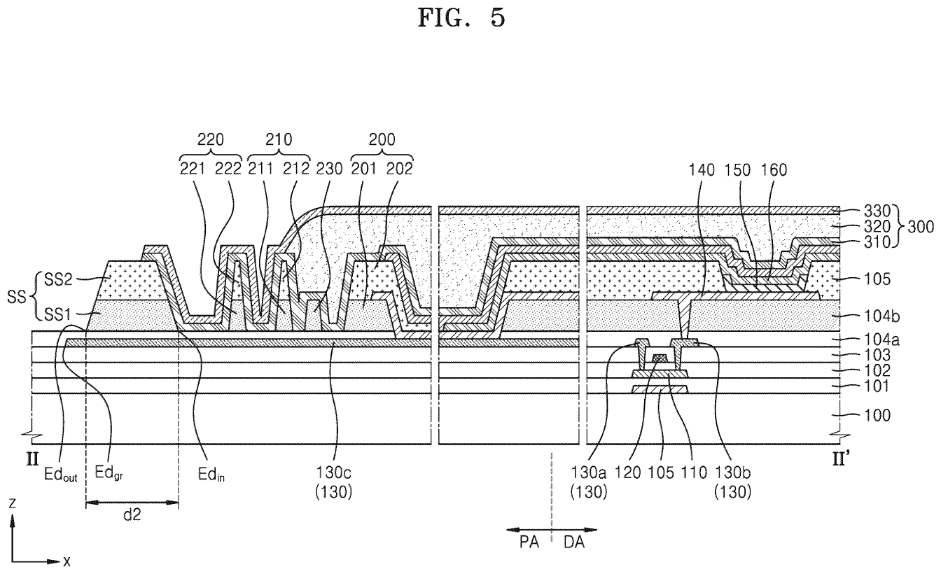

The second inorganic encapsulation layer 330 of the thin-film encapsulation layer 300 may extend to the peripheral area PA while covering the display area DA, to be in contact with the first inorganic encapsulation layer 310 at the outside of the organic encapsulation layer 320. FIG. 3 illustrates that the second inorganic encapsulation layer 330 extends to at least a portion of the outermost dam (e.g., a support structure SS). In reference to FIG. 3, FIG. 4, and FIG. 5, “outside” means farther from the display area DA, and “inside” means closer to the display area DA.

A common voltage line 130c may be a line configured to transmit a common voltage. The common voltage line 130c may be disposed on the same layer as the conductive layer 130 described above and may include the same material as that of the conductive layer 130. The common voltage line 130c may have the same layer structure as that of the conductive layer 130 described above.

The common voltage line 130c may be disposed below the support structure SS and the at least one dam 210, 220, and 230 in the peripheral area PA. The common voltage line 130c may overlap the support structure SS. The common voltage line 130c may overlap the at least one dam 210, 220, and 230. An end Ed_{gr} of the common voltage line 130c in the peripheral area PA may refer to the outermost end of the common voltage line 130c. In plan view, the end Ed_{gr} of the common voltage line 130c may overlap the support structure SS. The support structure SS may be disposed on the end Ed_{gr} of the common voltage line 130c, and the support structure SS may cover the end Ed_{gr} of the common voltage line 130c. In an embodiment, the end Ed_{gr} disposed at the outermost portion of the common voltage line 130c may be closer to the display area DA than an outer edge Edₒᵤₜ of the support structure SS. In an embodiment, the end Ed_{gr} disposed at the outermost portion of the common voltage line 130c may be covered by the support structure SS.

As the support structure SS covers the end Ed_{gr} of the common voltage line 130c, an arc phenomenon in which charges stored in a mask (see MM of FIG. 4) to be described below are transferred to the common voltage line 130c may be prevented. In order for the support structure SS to cover the end Ed_{gr} of the common voltage line 130c, a width d1 of the support structure SS may be greater than the width of a corresponding structure in conventional display aparatus. The “width” of the support structure SS may be measured at the base in the x-direction, where the support structure SS interfaces another layer (e.g., layer 104).

The support structure SS may be disposed in the peripheral area. The support structure SS may be disposed at the outer side of the at least one dam 210, 220, and 230. The support structure SS may be a member configured to support the mask (see MM of FIG. 4) used during a mask process, as in FIG. 5 described below. The mask (see MM of FIG. 4) according to an embodiment is described below.

The support structure SS is a structure that protrudes from the upper surface of the substrate 100 and may be referred to as a protrusion. The support structure SS may have a single-layer structure or a multilayer structure. The support structure SS having a two-layer structure is illustrated in FIG. 2. The support structure SS may be disposed at the outer side of the at least one dam 210, 220, and 230 and may protrude to the upper portion of the substrate.

A lower layer SS1 of the support structure SS may include the same material as that of the second organic insulating layer 104b. The lower layer SS1 of the support structure SS may be disposed on the same layer as the second organic insulating layer 104b. The lower layer SS1 of the support structure SS may have the same layer structure as that of the second organic insulating layer 104b. An upper layer SS2 of the support structure SS may include the same material as that of the pixel defining layer 105. The upper layer SS2 of the support structure SS may be disposed on the same layer as the pixel defining layer 105. The upper layer SS2 of the support structure SS may have the same layer structure as that of the pixel defining layer 105.

For example, because no organic material is disposed in an area between the second dam 220 and the support structure SS, ambient air may be effectively blocked from reaching the display area DA.

The width d1 of the support structure SS may refer to the width of the contact interface between the support structure SS and the layer underneath it in the x-direction. For example, the width d1 may be the distance between the outer edge Edₒᵤₜ and the inner edge Edᵢₙ of the support structure SS. As described above, to cover the end Ed_{gr} of the common voltage line 130c, the width d1 of the support structure SS may be greater than the width (see d2 of FIG. 5) of the support structure SS in the comparative example described below. For example, the width d1 of the support structure SS may be about 500 micrometers to about 1,000 micrometers. Specifically, the width d1 of the support structure SS may be about 650 micrometers. The width d1 of the support structure SS may be defined based on a direction from the display area DA to the peripheral area PA.

The support structure SS may include an outer edge Edₒᵤₜ and an inner edge Edᵢₙ. In a plan view, the distance between the outer edge Edₒᵤₜ and the inner edge Edᵢₙ may be the width of the support structure SS described above. In a plan view, the outer edge Edₒᵤₜ of the support structure SS may be disposed farther from the center of the display apparatus than the end Ed_{gr} of the common voltage line 130c. In plan view, the outer edge Edₒᵤₜ of the support structure SS may be disposed outside the end Ed_{gr} of the common voltage line 130c.

The inner side surface of the support structure SS may be covered by the first inorganic encapsulation layer 310 and the second inorganic encapsulation layer 330. The inner surface of the support structure SS may be covered by the first inorganic encapsulation layer 310 and the second inorganic encapsulation layer 330. A portion of the upper surface of the support structure SS may be covered by the first inorganic encapsulation layer 310 and the second inorganic encapsulation layer 330. A portion of the upper surface of the support structure SS covered by the first inorganic encapsulation layer 310 and the second inorganic encapsulation layer 330 may be an area of the upper surface of the support structure SS disposed on the inner side of the display apparatus.

The display apparatus according to an embodiment may include a substrate 100 including a display area DA in which an image is displayed and a peripheral area PA outside the display area DA. The display apparatus according to an embodiment may include a semiconductor layer 110 disposed on the substrate 100 above the display area DA, and a gate layer 120 disposed on the semiconductor layer 110 above the display area DA.

The display apparatus according to an embodiment may include a conductive layer 130 disposed on the gate layer 120 above the display area DA, the conductive layer 130 including a source electrode 130a and a drain electrode 130b electrically connected to the semiconductor layer 110, and at least one dam 210, 220, and 230 disposed on the conductive layer 130 above the peripheral area PA, and protruding from the upper portion of the substrate 100.

The display apparatus according to an embodiment may include a support structure SS disposed at the outer side of the at least one dam 210, 220, and 230 and protruding from the upper portion of the substrate 100, and a common voltage line 130c disposed between the substrate 100 and the support structure SS in the peripheral area PA, including an end Ed_{gr} overlapping the support structure SS in a plan view, and disposed on the same layer as the conductive layer 130.

In an embodiment, the width d1 of the support structure SS may be about 500 micrometers to about 1,000 micrometers. In an embodiment, the width d1 of the support structure SS may be about 650 micrometers. In an embodiment, the common voltage line 130c may be disposed on the same layer as the source electrode 130a and the drain electrode 130b.

In an embodiment, an area of the common voltage line 130c that overlaps the support structure SS in plan view may be on the same layer as the source electrode 130a and the drain electrode 130b.

In an embodiment, the at least one dam 210, 220, and 230 may include a first dam 210 disposed outside the display area DA and a second dam 220 disposed outside of the first dam 210. In an embodiment, in a plan view, the second dam 220 may be between the first dam 210 and the support structure SS.

In an embodiment, the support structure SS and the at least one dam 210, 220, and 230 may each have a multilayer structure. A lower layer SS1 of the support structure SS and lower layers 211, 221, and 230 of the at least one dam 210, 220, and 230 may be formed on the same layer and may include the same material.

In an embodiment, an upper layer SS2 of the support structure SS and upper layers 212 and 222 of the at least one dam 210, 220, and 230 may be formed on the same layer and may include the same material. In the embodiment depicted in FIG. 3, there is no upper layer in the additional dam 230; however, this is not a limitation of the inventive concept.

In an embodiment, the upper layer SS2 of the support structure SS may be disposed on the lower layer SS1 of the support structure SS, and the lower surface of the upper layer SS2 of the support structure SS and the upper surface of the lower layer SS1 of the support structure SS may be in direct contact with each other.

In an embodiment, in plan view, the common voltage line 130c may overlap the support structure SS and the at least one dam 210, 220, and 230. As a result, the common voltage line 130c may be electrically connected to an opposite electrode 160, and when charges of a mask (see MM of FIG. 4) is transferred to the common voltage line 130c, a pixel circuit may be affected. To prevent such an effect, the width d1 of the support structure SS is changed.

In an embodiment, the display apparatus may further include an inorganic insulating layer 102 between the semiconductor layer 110 and the gate layer 120, first and second organic insulating layers 104a and 104b on the conductive layer 130, a pixel electrode 140 on the first and second organic insulating layers 104a and 104b, an intermediate layer 150 on the pixel electrode 140, an opposite electrode 160 on the intermediate layer 150 and electrically connected to the common voltage line 130c in the peripheral area PA, and a thin-film encapsulation layer 300 on the opposite electrode 160.

In an embodiment, the thin-film encapsulation layer 300 may further include a first inorganic encapsulation layer 310 on the opposite electrode 160, an organic encapsulation layer 320 on the first inorganic encapsulation layer 310, and a second inorganic encapsulation layer 330 on the organic encapsulation layer 320. The organic encapsulation layer 320 may be in contact with the inner surface of the at least one dam 210, 220, and 230 (e.g., the inner surface of the first dam 210).

FIG. 4 is a diagram for describing the support structure SS illustrated in FIG. 3.

In the following description of FIG. 4, the same or redundant description as provided above may be omitted.

As illustrated in FIG. 4, a mask support MS may be provided on one side of a mask MM. The mask support MS may be engaged with the support structure SS of the display apparatus to support the mask MM. The support structure SS may include an organic material and may have a buffering effect when supporting the mask MM. In addition to supporting the mask MM, the support structure SS may also prevent cracks from being transferred to the display area.

A first-1 distance d1-1 may refer to a width of an area where the support structure SS and the mask MM do not overlap each other. A first-2 distance d1-2 may refer to a width of an area where the support structure SS and the mask MM overlap each other. The first-1 distance d1-1 may be less than the first-2 distance d1-2. The first-2 distance d1-2 may be greater than the first-1 distance d1-1. As the first-1 distance d1-1 is less than the first-2 distance d1-2, a threshold voltage at which an arc phenomenon occurs between the end Ed_{gr} of the common voltage line 130c and the edge of the mask MM may increase.

For example, the first-1 distance d1-1 may be about 100 micrometers to about 200 micrometers. Specifically, the first-1 distance d1-1 may be about 100 micrometers. When the first-1 distance d1-1 is less than 100 micrometers, stable disposition of the mask support MS may be difficult, and when the first-1 distance d1-1 is greater than 200 micrometers, an arc phenomenon may occur more easily between the end Ed_{gr} of the common voltage line 130c and the edge of the mask MM.

For example, the first-2 distance d1-2 may be about 400 micrometers to about 800 micrometers. Specifically, the first-2 distance d1-2 may be about 500 micrometers. When the first-2 distance d1-2 is less than 400 micrometers, an arc phenomenon may occur more easily between the end Ed_{gr} of the common voltage line 130c and the edge of the mask MM, and when the first-2 distance d1-2 is greater than 800 micrometers, stable disposition of the mask support MS may be difficult.

In an embodiment, a distance between the end Ed_{gr} of the common voltage line 130c and the edge of the mask MM (or a distance dv between the upper surface of the common voltage line 130c and the lower surface of the mask MM) may be less than the width d1 of the support structure SS. The width d1 of the support structure SS may be greater than the distance between the end Ed_{gr} of the common voltage line 130c and the edge of the mask MM (or the distance dv between the upper surface of the common voltage line 130c and the lower surface of the mask MM). Accordingly, the end Ed_{gr} of the common voltage line 130c may be more easily covered by the support structure SS.

In an embodiment, the width d1 of the support structure SS may be greater than the width of the mask support MS. Because the width d1 of the support structure SS is greater than the width of the mask support MS, a stable disposition of the mask MM may be achieved.

In an embodiment, the support structure SS may include a first area that does not overlap the mask MM disposed on the support structure SS in plan view and a second area that overlaps the mask MM disposed on the support structure SS in plan view. In an embodiment, a width d1-2 of the second area may be greater than a width d1-1 of the first area. Because the width d1-2 of the second area is greater than the width d1-1 of the first area, shielding of the common voltage line 130c may be facilitated.

FIG. 5 is a cross-sectional view schematically illustrating a portion of a peripheral area and a portion of a display area in a display apparatus according to a comparative example.

In the following description of FIG. 5, the same or redundant description as provided above may be omitted.

As illustrated in FIG. 5, a support structure SS of a display apparatus according to a comparative example may have a width equal to a second distance d2 in a plan view. The second distance d2 may be less than the first distance d1 described above.

As a result, an end Ed_{gr} of a common voltage line 130c extends beyond the support structure SS and may not be covered by the support structure SS. After a mask MM is installed, charges may be stored in the mask MM. When the end Ed_{gr} of the common voltage line 130c is not covered by the support structure SS, charges in the mask MM may be transferred to the common voltage line 130c (to which a ground voltage is transferred). This phenomenon may be called an arc phenomenon. The arc phenomenon may damage the display panel 10 and may cause defects. The arc phenomenon occurs more easily in a shape with sharp edges.

To avoid the problem illustrated with the example of FIG. 5, the edge of the support structure SS and the end of the common voltage line 130c are arranged to overlap each other in accordance with the embodiments of FIGS. 3 and 4.

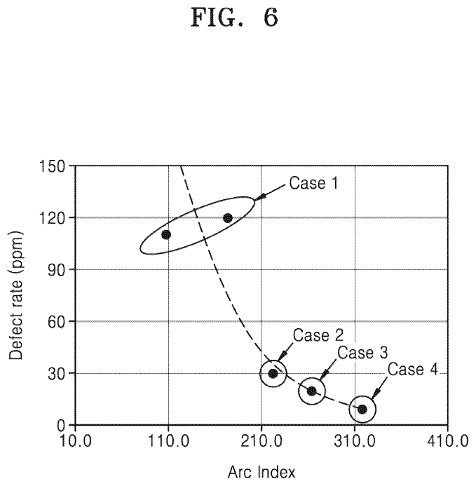

FIG. 6 is a graph schematically showing a defect rate according to the width of the support of FIG. 3.

In FIG. 6, the y-axis represents a defect rate and the x-axis represents an arc index. At this time, the arc index may be defined as the product of a threshold voltage, a capacitance, and a thickness of an insulating layer. Referring to FIG. 6, four cases are identified.
Case 1 is a case where the width of the support structure SS is about 350 micrometers.
Case 2 is a case where the width of the support structure SS is about 650 micrometers.
Case 3 is a case where the width of the support structure SS is about 650 micrometers and the length of the common voltage line 130c is greater than the length of the common voltage line 130c in the other cases.
Case 4 is a case where the width of the support structure SS is about 650 micrometers and one end of the common voltage line 130c is covered by the lower portion of the support structure SS.

Referring to FIG. 6, the defect rate of Case 1 is the highest and the defect rate of Case 4 is the lowest. The arc index is the highest in Case 4. Usually, the higher the arc index, the less frequently the arc phenomenon occurs.

Therefore, using the condition of Case 4 in actual product production may maximize the yield. Case 2 and Case 3 also have acceptable defect rates and may therefore be used in actual product production.

According to one or more embodiments as described above, a display apparatus in which an occurrence of an arc phenomenon is prevented or reduced may be implemented. The scope of the disclosure is not limited by such an effect.

The display panel 10 may be incorporated in a display device or an electronic device, including portable electronic devices such as mobile phones, smartphones, tablet personal computers (PCs), mobile communication terminals, electronic notebooks, e-books, portable multimedia players (PMPs), navigations, and ultra mobile PCs (UMPCs), but also televisions (TVs), laptops, monitors, billboards, Internet of Things (loT), or the like. According to an embodiment, the display panel 10 may also be used in electronic devices including wearable devices such as smart watches, watch phones, glasses-type displays, or head mounted displays (HMDs). According to an embodiment, the display panel 10 may also be used in electronic devices in dashboards of vehicles, center information displays (CIDs) of the center fascia or dashboards of vehicles, mirror displays that replace the side view mirrors of vehicles, and display screens arranged on the rear sides of front seats to serve as entertainment devices for back seat passengers of vehicles.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus having a display area and a peripheral area, comprising:
a substrate in the display area in which an image is displayed and the peripheral area outside the display area;
a semiconductor layer disposed on the substrate in the display area and;
a gate layer disposed on the semiconductor layer;
a conductive layer disposed on the gate layer, the conductive layer comprising a source electrode, a drain electrode, and a common voltage line, the source electrode and the drain electrode being electrically connected to the semiconductor layer in the display area and the common voltage line disposed in the display area and the peripheral area;
at least one dam disposed on the conductive layer in the peripheral area;
a support structure disposed outside of the at least one dam and overlapping an end of the common voltage line.

2. The display apparatus of claim 1, wherein the end of the common voltage line in the peripheral area is closer to the display area than an outer edge of the support structure.

3. The display apparatus of claim 1, wherein the end of the common voltage line is covered by the support structure in the peripheral area.

4. The display apparatus of claim 1, further comprising:
a mask support disposed on the support structure; and
a mask disposed on the mask support.

5. The display apparatus of claim 4, wherein a distance between the end of the common voltage line and an edge of the mask is less than a width of a base of the support structure.

6. The display apparatus of claim 4, wherein a width of the support structure is greater than a width of the mask support.

7. The display apparatus of claim 4, wherein the support structure comprises a first area that does not overlap the mask and a second area that overlaps the mask.

8. The display apparatus of claim 7, wherein a width of the second area is greater than a width of the first area.

9. The display apparatus of claim 1, wherein a width of a base of the support structure is about 500 micrometers to about 1,000 micrometers.

10. The display apparatus of claim 9, wherein the width of the base of the support structure is about 650 micrometers.

11. The display apparatus of claim 1, wherein the common voltage line is disposed on a same layer as the source electrode and the drain electrode.

12. The display apparatus of claim 1, wherein an area of the common voltage line that overlaps the support structure is on a same layer as the source electrode and the drain electrode.

13. The display apparatus of claim 1, wherein the at least one dam comprises a first dam disposed outside the display area and a second dam disposed outside of the first dam, and wherein the second dam is between the first dam and the support structure.

14. The display apparatus of claim 1, wherein each of the support structure and the at least one dam has a multilayer structure, and
a lower layer of the support structure and a lower layer of the at least one dam are formed on a same layer and include a same material,
wherein an upper layer of the support structure and an upper layer of the at least one dam are formed on a same layer and include a same material.

15. The display apparatus of claim 14, wherein the upper layer of the support structure is disposed on the lower layer of the support, and a lower surface of the upper layer of the support is in direct contact with an upper surface of the lower layer of the support.

16. The display apparatus of claim 1, wherein the common voltage line overlaps the support structure and the at least one dam.

17. The display apparatus of claim 1, further comprising:
an inorganic insulating layer between the semiconductor layer and the gate layer;
an organic insulating layer disposed on the conductive layer;
a pixel electrode disposed on the organic insulating layer;
an intermediate layer disposed on the pixel electrode;
an opposite electrode disposed on the intermediate layer and electrically connected to the common voltage line in the peripheral area; and
a thin-film encapsulation layer disposed on the opposite electrode.

18. The display apparatus of claim 1, wherein the thin-film encapsulation layer comprises:
a first inorganic encapsulation layer disposed on the opposite electrode;
an organic encapsulation layer disposed on the first inorganic encapsulation layer; and
a second inorganic encapsulation layer disposed on the organic encapsulation layer,
wherein the organic encapsulation layer is in contact with an inner side surface of the at least one dam.

19. An electronic device comprising:
a substrate in a display area and a peripheral area;
a thin-film transistor in the display area, the thin-film transistor including a semiconductor layer, a gate layer on the semiconductor layer, and a conductive layer disposed on the gate layer, wherein the conductive layer comprises a common voltage line that starts in the display area and has an end in the peripheral area;
a dam disposed on the common volage line in the peripheral area; and
a support structure disposed outside of the dam and overlapping the end of the common voltage line.

20. The electronic device of claim 19, further comprising:
a mask support on the support structure; and
a mask disposed on the mask support, the mask extending beyond a sidewall o the support structure.
